(19) United States
(12) Patent Application Publication
(10) Pub. No.: US 2008/0314559 A1
(43) Pub. Date: Dec. 25, 2008

(54) HEAT EXCHANGE STRUCTURE AND HEAT DISSIPATING APPARATUS HAVING THE SAME

(76) Inventors: I-Ta HSU, Chung-Ho City (TW); Chih-Peng Liao, Chung-Ho City (TW)

Correspondence Address: HDSL, P.O. BOX 220746, CHANTILLY, VA, 20153-0746, US

(21) Appl. No.: 11/766,186

(22) Filed: Jun. 21, 2007

(51) Int. Cl. F28F 7/02; H05K 7/20

(52) U.S. Cl. 165/80.4; 165/143; 165/164; 361/699

(57) ABSTRACT

A heat exchange structure is connected to a dual water cooling system and a heat dissipating apparatus has the heat exchange structure. The heat exchange structure includes a box as a main body, and the box includes a first cavity and a second cavity. The first cavity and the second cavity are interconnected with separate water cooling systems, wherein the first cavity includes a first chamber, and the first cavity has a water inlet pipeline and a water outlet pipeline, both interconnected to the first chamber. The second cavity includes a second chamber, and the second cavity has a water inlet pipeline and a water outlet pipeline, both interconnected to a second chamber. A heat conducting plate is disposed at a position that connects the first cavity and the second cavity for providing a heat conducting path of the first cavity and the second cavity.

### BACKGROUND OF THE INVENTION

1. Field of the Invention

The present invention relates to a heat dissipating apparatus, and more particularly to a heat sink having a dual water cooling system.

2. Description of Prior Art

In the high-precision technology related industry, it is a common goal for manufacturers to design compact products especially for electronic components, and the heat produced during the operation of these compact electronic components increases greatly. To prevent the temperature effect caused by heat from adversely affecting the operation of electronic components, both manufacturers and users start paying more attention to appropriate heat dissipation, and thus it is quite popular to install a heat dissipating apparatus directly to the electronic component.

In general, a water cooling heat dissipating system is one of the widely used heat dissipation technologies for satisfying the heat dissipation requirement of a computer while taking the limited internal space of the computer into consideration. For instance, a water cooling connector is installed directly to a heat-generating electronic component to exchange heat through a coolant liquid to assist lowering the temperature of the electronic components, and a duct is connected to a heat dissipating radiator and a pump to form a heat dissipating system. The pump is provided for producing a compression effect, so that coolant liquid can flow through each component to exchange heat and achieve the effect of dissipating heat.

Although the coolant liquid flowing inside the water cooling system can carry away the heat source on the electronic components by heat exchange, the heat can be dissipated to the air through the coolant liquid by the heat dissipating radiator, in hope of dispersing the heat absorbed by the coolant liquid to the outside. However, the heat dissipating radiator adopts heat conduction and air to perform a heat dissipation through the coolant liquid, and the heat dissipating efficiency is not in conformity with the flowing speed of the coolant liquid, so that the coolant liquid without completing the heat dissipation is circulated and returned to the water cooling connector, and the heat dissipating performance of the water cooling system is affected greatly.

To overcome the aforementioned shortcomings, a conventional method adds a fan to the heat dissipating radiator, so that the air flow produced by the fan compulsorily speeds up the heat dissipating effect of the coolant liquid in the heat dissipating radiator, but the air cooling effect of both fan and heat dissipating radiator cannot disperse the heat source in the coolant liquid to the outside effectively and efficiently due to the flowing speed of the coolant liquid, and thus the coolant liquid with heat is circulated back into the water cooling connector, and the heat absorbing effect of the coolant liquid is still insufficient, and the overall heat dissipating performance is affected. Such conventional method definitely requires further improvements.

### SUMMARY OF THE INVENTION

In view of the foregoing shortcomings of the prior art, the inventor of the present invention based on years of experience in the related industry to conduct experiments and modifications, and finally developed a heat exchange structure and a heat dissipating apparatus having the heat exchange structure in accordance with the present invention to overcome the shortcomings of the prior art.

The present invention is to provide a heat exchange structure of a dual water cooling system and a heat dissipating apparatus having the heat exchange structure, wherein separate water cooling systems are installed to the same heat dissipating apparatus, so that the water cooling effect of a water cooling system and the conduction effect of a heat exchange structure can assist dissipating the heat of the working fluid of another water cooling heat dissipating system, and the performance of the working fluid for circulating and absorbing heat is enhanced greatly.

The present invention provides a heat exchange structure and a heat dissipating apparatus having the heat exchange structure, wherein a box composed of a first cavity and a second cavity constitutes the main body of heat exchange the structure, and the first cavity and the second cavity are interconnected to the separate water cooling systems respectively. The first cavity includes a first chamber therein, and the first chamber has a water inlet pipeline and a water outlet pipeline, both disposed on the first cavity and interconnected with the first chamber. The second cavity includes a second chamber therein, and a water inlet pipeline and a water outlet pipeline, both disposed on the second cavity and interconnected with the second chamber. A heat conducting plate is disposed at a position that connects the first cavity and the second cavity for providing a thermal conducting path of the first cavity and the second cavity.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is an exploded view of the present invention;

FIG. 2 is a perspective view of the present invention;

FIG. 3 is an exploded view of another preferred embodiment of the present invention;

FIG. 4 is a section view of the operation of the present invention;

FIG. 5 is a perspective view of an apparatus of the present invention;

FIG. 6 is an exploded view of the structure of an apparatus of the present invention; and

FIG. 7 is a perspective view of an apparatus of another preferred embodiment of the present invention.

### DETAILED DESCRIPTION OF THE INVENTION

The technical characteristics, features and advantages of the present invention will become apparent in the following detailed description of the preferred embodiments with reference to the accompanying drawings. The drawings are provided for reference and illustration only, but not intended for limiting the present invention.

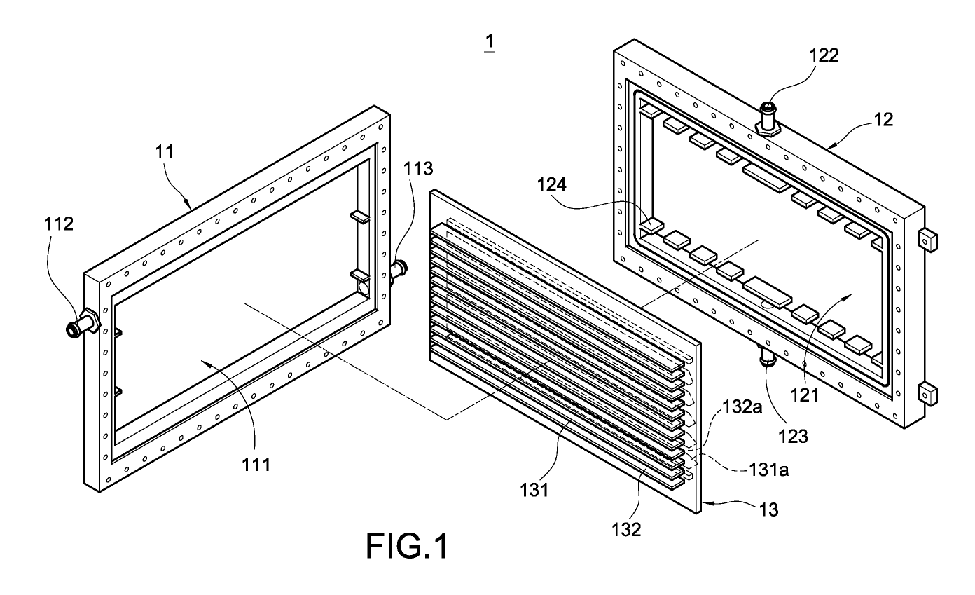

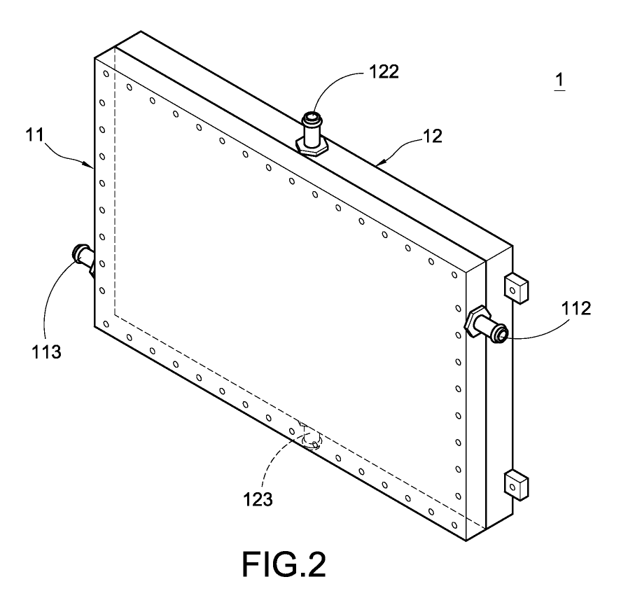

Referring to FIG. 1 for an exploded view of the present invention, a heat exchange structure of the invention comprises a box 1 as its main body, and the box 1 is composed of a first cavity 11 and a second cavity 12 identical in shape, and the first cavity 11 and the second cavity 12 of this embodiment are in a rectangular shape (but the box 1 is not limited to the rectangular shape). A first chamber 111 and a second chamber 121 are disposed in the first cavity 11 and the second cavity 12 respectively for containing a working fluid, and at least one water inlet pipeline 112 and at least one water outlet pipeline 113 are disposed on left and right sides of the first cavity 11 respectively and interconnected with the interior of the first chamber 111, and at least one water inlet pipeline 122 and at least one water outlet pipeline 123 are disposed at top and bottom sides of the second cavity 12 respectively and interconnected with the interior of the second chamber 121. A plurality of stopping plates 124 are installed at the periphery of the second chamber 121 for perturbing the flowing direction of the working fluid, and a heat conducting plate 13 is installed at the joint surface of the first cavity 11 and the second cavity 12, and the heat conducting plate 13 is made of a thermal conducting material, such that when the heat conducting plate 13 corresponding to the first cavity 11 and the second cavity 12 is assembled, the first chamber 111 and the second chamber 121 are sealed completely, and the first chamber 111 and the second chamber 121 are not interconnected with each other. A plurality of fins 131 are disposed on a plate surface of the heat conducting plate 13a corresponding to the first chamber 111 are arranged with an interval apart from each other, and every two adjacent fins 131 form a passage 132. A plurality of fins 131a are also disposed on another plate surface of the heat conducting plate 13 corresponding to the second chamber 121, and the fins 131a of this embodiment are in a triangular shape for increasing the contact area with the working fluid, and every two adjacent fins 131a form a passage 132a, and the assembled structure is shown in FIG. 2.

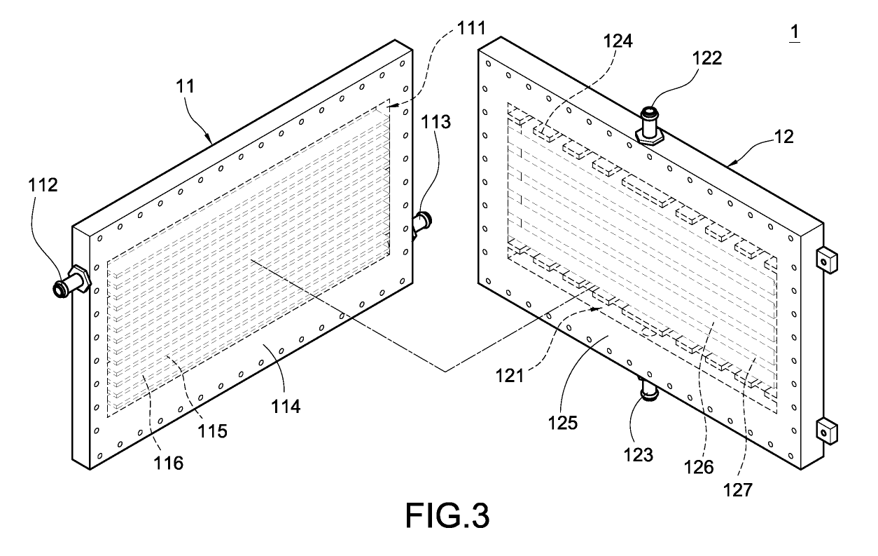

Referring to FIG. 3 for an exploded view of another preferred embodiment of the present invention, the box 1 can be a structure composed of a first cavity 11, a second cavity 12 and a heat conducting plate 13, or composed of the first cavity 11 and the second cavity 12 made of conducting materials as shown in the figure. The first cavity 11 and the second cavity 12 are sealed, and the first cavity 11 and the second cavity 12 include a first chamber 111 and a second chamber 121 therein respectively. At least one water inlet pipeline 112 and at least one water outlet pipeline 113 are disposed on left and right sides of the first cavity 11 respectively and interconnected with the interior of the first chamber 111. At least one water inlet pipeline 122 and at least one water outlet pipeline 123 are disposed at top and bottom sides of the second cavity 12 respectively and interconnected with the interior of the second chamber 121. The first cavity 11 and the second cavity 12 separately have a joint surface 114, 125, such that the corresponding joint surfaces 114, 125 act as interfaces for the thermal conduction. In addition, the first chamber 111 and the second chamber 121 install a plurality of fins 115, 126 therein respectively, and any two adjacent fins 115, 126 form a passage 116, 127 to increase the heat dissipating area inside the first chamber 111 and the second chamber 121. A plurality of stopping plates 124 are disposed at the periphery of the second chamber 121 for perturbing the flowing direction of the working fluid.

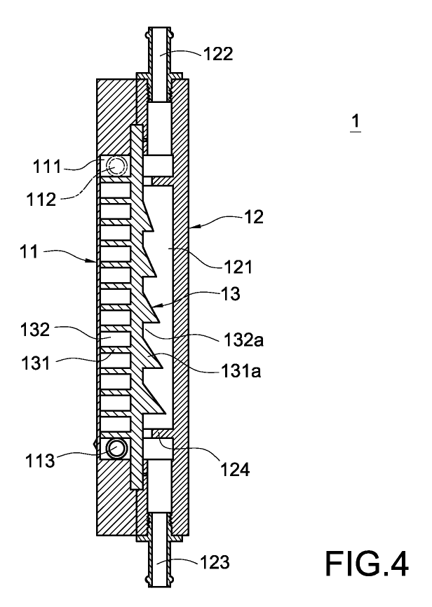

Referring to FIG. 4 for a section view of the operation of the present invention, the first cavity 11 and the second cavity 12 are interconnected with separate water cooling systems, wherein the water cooling systems are attached to heat generating components for dissipating heat. When the working fluid with absorbed heat enters into the second cavity 12 from the water inlet pipeline 122 and distributes uniformly in the second chamber 121 according to the passages 132a formed by the fins 131a in the second chamber 121, the working fluid and fins 131a are used to carry out the heat dissipation, and the heat is conducted from the fins 131a to the plurality of fins 131 on another surface of the heat conducting plate 13 through the heat conducting plate 13, and then the working fluid flows out of the water outlet pipeline 123, and the coolant liquid flows from the water inlet pipeline 112 into the first chamber 111 through the interior of the first cavity 11, and distributes uniformly in the first chamber 111 according to the passages 132 formed by the plurality of fins 131 inside the first chamber 111 and exchanges heat with the heat source absorbed by each fin 131 and carries away the heat source of a heat generating component absorbed by another water cooling system. Finally, the coolant liquid with absorbed heat source is guided out of the water outlet pipeline 113, and then entered into other heat dissipating components for dissipating heat, and finally circulated back into the system for the heat dissipation again.

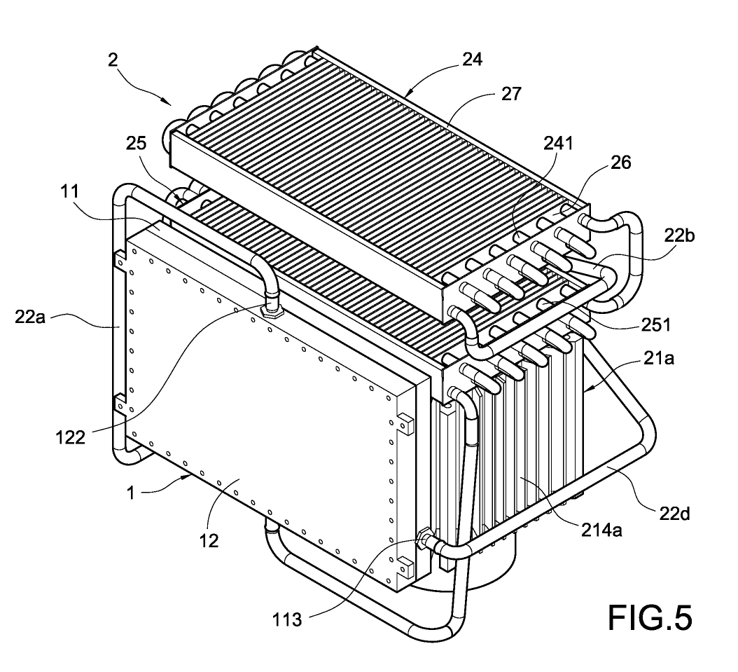

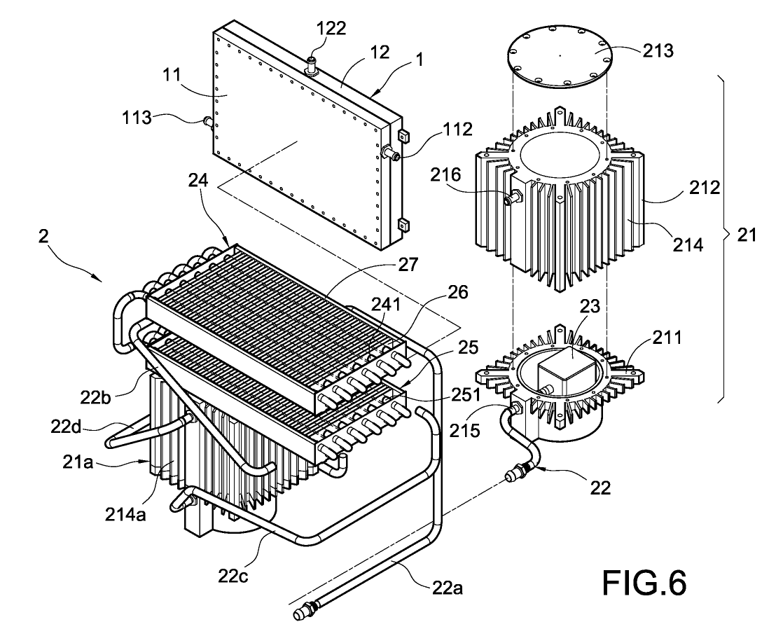

Referring to FIGS. 5 and 6 for a perspective view and an exploded view of the structure of a heat dissipating apparatus having a heat exchange structure in accordance with the present invention respectively, the apparatus 2 is a heat dissipating apparatus of a dual water cooling system, wherein the apparatus comprises a plurality of water tanks 21, 21a, and the water tank 21 is composed of a containing groove 211, a hollow pillar 212 and a lid 213. In the meantime, a plurality of fins 214 in a radiating form are disposed at the external periphery of the pillar 212 in the containing groove 211 and interconnected to a water outlet pipeline 215 and a water inlet pipeline 216 of the containing groove 211 and the pillar respectively, and the water outlet pipeline 215 and the water inlet pipeline 216 are connected separately to a duct 22 and interconnected with other components. In this embodiment, the containing groove 211 further includes a pump 23 therein, and the pump 23 is interconnected with the outlet pipeline 215 through the duct 22 for pumping the working fluid out from the water tank 21, and the position for installing the pump 23 is not limited to a position inside the containing groove 211 only. The apparatus 2 includes a water tank 21 connected to a water cooling connector (not shown in the figure) through the duct 22 and then connected to the second cavity 12 of the heat exchange structure, and finally the second cavity 12 is interconnected with the water tank 21 through a duct 22b, and another water tank 21a is interconnected with the first cavity 11 of the heat exchange structure through a duct 22c. Further, the top of the water tank 21, 21 includes at least one heat dissipating radiator, and a plurality of heat dissipating radiators 24, 25 are installed in this preferred embodiment, wherein the heat dissipating radiators 24, 25 are composed of a plurality of fins 26 and a plurality of metal pipes 241, 251, and the metal pipes 241, 251 are interconnected with the duct 22b and the water outlet pipeline 123.

When the working fluid enters into the water cooling connector structure (not shown in the figure) through the duct 22 for dissipating heat, the working fluid carries away the heat source absorbed by the water cooling connector, and the working fluid flows from the duct 22a into the second cavity 12 of the heat exchange structure and disperses uniformly in the second chamber 121 according to the passages 132a formed by the fins 131a in the second chamber 121, such that the working fluid and the fin 131a can carry out the heat exchange and conduct the heat from the fins 131a to a plurality of fins 131 on another surface of the heat conducting plate 13 through the heat conducting plate, and the working fluid is guided out of the water outlet pipeline 123, and the working fluid passes through the heat dissipating radiator 24 for dissipating heat, and finally returns into the water tank 21 through the duct 22b, and the working fluid conducts the incompletely dissipated heat source to the outside through the fins 214 along the periphery of the water tank 21, and a pump 23 (not shown in the figure) installed in another water tank 21a pumps the coolant liquid into the first cavity 11 of the heat exchange structure through the duct 22c and distributes uniformly in the first chamber 111 according to the passages 132 formed by the plurality of fins 131 in the first chamber 111 and simultaneously exchanges heat with the heat source absorbed by the fins 131 and carries away the heat source of the heat generating component from another water cooling system. And then, the coolant liquid with the absorbed heat source is guided out from the water outlet pipeline 113, and finally returned into the water tank 21a through a duct 22d. The heat absorbed by the coolant liquid is dissipated to the outside by a plurality of fins 214a disposed at the periphery of the water tank 21a, so as to achieve the heat dissipating effect. Further, the water tank 21a can be connected to a heat dissipating radiator to assist the heat dissipation and enhance the heat dissipating performance of the water tank 21a.

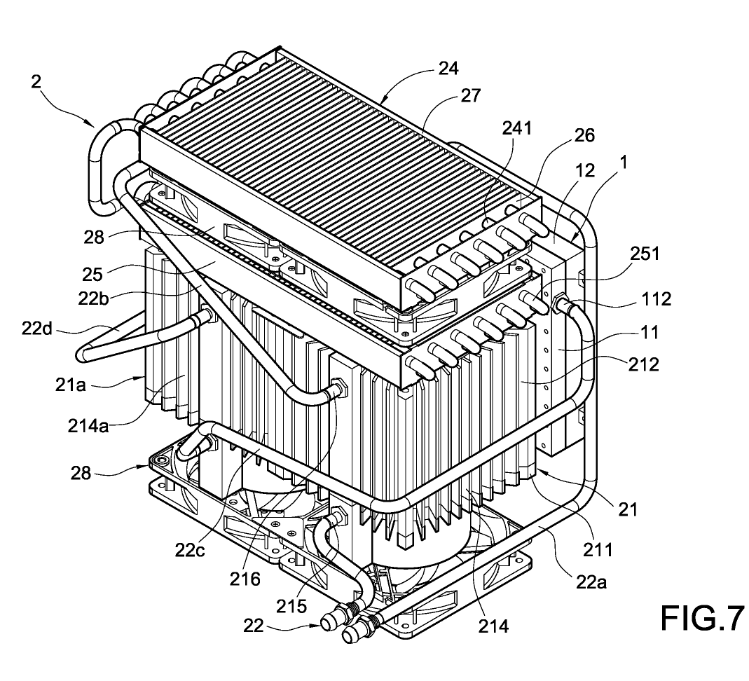

Referring to FIG. 7 for a perspective view of the structure of another apparatus of the present invention, at least one fan 28 (or a plurality of fans as used in this embodiment) is installed at the bottom of the plurality of water tanks 21, 21a, and a plurality of fans 28 are also installed among the loop of the duct 22 between the heat dissipating radiators 24, 25, so that the compulsory air flow produced by the fan 28 assists the heat dissipations by the fins 214, 214a at the external periphery of the water tanks 21, 21a and the heat dissipating radiators 24, 25, and the compulsory air flow carries the hot air away, so as to prevent the hot air from being accumulated to produce a temperature effect or affecting the overall heat dissipating performance.

The present invention is illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A heat exchange structure, comprising:
a first cavity, including a first chamber therein, and a water inlet pipeline and a water outlet pipeline thereon, and the water inlet pipeline, the water outlet pipeline and the first chamber being interconnected and provided for entering a working fluid into the first chamber; and
a second cavity, engaged with the first cavity, for conducting heat of a heat source to each other, and the second cavity including a second chamber therein, and a water inlet pipeline and a water outlet pipeline thereon, and the water inlet pipeline, the water outlet pipeline and the second chamber being interconnected and provided for entering a working fluid into the second chamber.

2. The heat exchange structure of claim 1, wherein the first cavity and the second cavity are made of a thermal conducting material.

3. The heat exchange structure of claim 2, wherein the first cavity has a joint surface, and the second cavity has another joint surface coupled with the joint surface of the first cavity.

4. The heat exchange structure of claim 1, wherein the first chamber includes a plurality of fins therein.

5. The heat exchange structure of claim 4, wherein any two adjacent fins form a passage.

6. The heat exchange structure of claim 1, wherein the second chamber includes a plurality of fins therein.

7. The heat exchange structure of claim 6, wherein any two adjacent fins form a passage.

8. The heat exchange structure of claim 1, further comprising a heat conducting plate disposed at a position that connects the first cavity and the second cavity, and the heat conducting plate precisely sealing the first chamber and the second chamber, such that the first chamber is not interconnected to the second chamber.

9. The heat exchange structure of claim 8, wherein the heat conducting plate has a plurality of fins disposed on two plate surfaces thereof

10. The heat exchange structure of claim 9, wherein any two adjacent fins on the two plate surfaces form a heat dissipating passage.

11. The heat exchange structure of claim 9, wherein the fin on one of the plate surfaces is in a triangular shape.

12. The heat exchange structure of claim 8, wherein the second chamber has a plurality of stopping plates disposed at an internal periphery of the second chamber.

13. The heat exchange structure of claim 1, wherein the second chamber has a plurality of stopping plates disposed at an internal periphery of the second chamber.

14. A heat dissipating apparatus having a heat exchange structure, comprising:
a plurality of water tanks, for containing a working fluid, and the water tanks being not interconnected with each other, and each water tank having a water inlet pipeline and a water outlet pipeline;
a plurality of ducts, interconnected with the water inlet pipeline and the water outlet pipeline respectively;
a plurality of pumps, interconnected with the plurality of water tanks, respectively; and
a heat exchange structure, having a first cavity and a second cavity engaged with each other, and the first cavity being interconnected with one water tank and one pump, and the second cavity being interconnected with another water tank and another pump by the ducts, respectively.

15. The heat dissipating apparatus having a heat exchange structure of claim 14, wherein the water tank includes a containing groove, a hollow pillar and a lid.

16. The heat dissipating apparatus having a heat exchange structure of claim 15, wherein the water tank includes a plurality of fins disposed at a external periphery of the water tank.

17. The heat dissipating apparatus having a heat exchange structure of claim 16, wherein the plurality of fins are substantially in a radiating form.

18. The heat dissipating apparatus having a heat exchange structure of claim 14, wherein the pump is installed inside the water tank.

19. The heat dissipating apparatus having a heat exchange structure of claim 14, further comprising at least one heat dissipating radiator interconnected to the ducts and the water outlet pipeline.

20. The heat dissipating apparatus having a heat exchange structure of claim 19, wherein the heat dissipating radiator is formed by passing a plurality of metal pipes through the plurality of fins.

21. The heat dissipating apparatus having a heat exchange structure of claim 19, wherein the heat dissipating radiator includes at least one fan installed on a lateral side of the heat dissipating radiator.

22. The heat dissipating apparatus having a heat exchange structure of claim 14, wherein the water tank includes at least one fan installed on a lateral side of the water tank.

23. The heat dissipating apparatus having a heat exchange structure of claim 14, wherein the first cavity further includes a first chamber therein, and the first chamber further includes a water inlet pipeline and a water outlet pipeline, and the water inlet pipeline and the water outlet pipeline are interconnected to the first chamber.

24. The heat dissipating apparatus having a heat exchange structure of claim 23, wherein the first chamber includes a plurality of fins therein.

25. The heat dissipating apparatus having a heat exchange structure of claim 24, wherein any two adjacent fins form a passage.

26. The heat dissipating apparatus having a heat exchange structure of 14, wherein the second cavity further includes a second chamber, and the second cavity further includes a water inlet pipeline and a water outlet pipeline, and the water inlet pipeline and the water outlet pipeline are interconnected to the second chamber.

27. The heat dissipating apparatus having a heat exchange structure of claim 26, wherein the second chamber includes a plurality of fins therein.

28. The heat dissipating apparatus having a heat exchange structure of claim 27, wherein any two adjacent fins form a passage.

29. The heat dissipating apparatus having a heat exchange structure of claim 26, wherein the second chamber includes a plurality of stopping plates disposed at an internal periphery of the second chamber.

30. The heat dissipating apparatus having a heat exchange structure of claim 14, wherein the first cavity has a joint surface, and the second cavity has another joint surface coupled with the joint surface of the first cavity.

31. The heat dissipating apparatus having a heat exchange structure of claim 14, further comprising a heat conducting plate disposed at a position that connects the first cavity and the second cavity, and the heat conducting plate precisely seals the first cavity and the second cavity, and the first cavity and the second cavity are not interconnected with each other.

32. The heat dissipating apparatus having a heat exchange structure of claim 31, wherein two plate surfaces of the heat conducting plate separately have a plurality of fins.

33. The heat dissipating apparatus having a heat exchange structure of claim 32, wherein any two adjacent fins on the two plate surfaces form a heat dissipating passage.

34. The heat dissipating apparatus having a heat exchange structure of claim 32, wherein the fin on one of the plate surfaces is substantially in a triangular shape.
